(19) United States
(12) Patent Application Publication
(10) Pub. No.: US 2006/0128172 A1
(43) Pub. Date: Jun. 15, 2006

(54) Coaxial connector

(75) Inventors: Min Lung Chien, Hsin Tien, Taipei (TW); Ching Tien Chen, Hsin Tien, Taipei (TW); Kai Ray Cheng, Hsin Tien, Taipei (TW)

Correspondence Address: MICHAEL LIN, 5F 79 Roosevelt Rd. Sec. 2, TAIPEI, 106, TW

(73) Assignee: ADVANCED CONNECTEK INC., Hsin Tien, Taipei (TW)

(21) Appl. No.: 10/907,106

(22) Filed: Mar. 21, 2005

(30) Foreign Application Priority Data
Dec. 10, 2004 (TW) 093219953

(51) Int. Cl. H05K 1/00

(52) U.S. Cl. 439/63

(57) ABSTRACT

The present invention discloses a coaxial cable connector and an assembly method for the same, which includes a metal shell, an insulating member, a terminal seat and an under cover; the insulating member has a chassis on the lower side of the cylinder thereof, the terminal seat has a retaining room on the upper side of the retaining chamber thereof, the two sides of the base plate of the metal shell each is bent downward into an holding portion, the holding portion is bent inward into an abutting portion, the insulating member is placed on the terminal seat, the terminal seat and the under cover are wrapped by the metal shell, the terminal seat is formed by insert molding; therefore, the present invention provides the advantages which could achieve a perfect plane degree, control the terminal positions precisely and avoid poor contacting etc, make the coaxial cable connector is adapted to the producing process in which multi-group of connectors are manufactured jointly.

### FIELD OF THE INVENTION

The present invention refers to a coaxial cable connector, especially, to a connector in which the terminals of the terminal seat are placed into the housing by insert molding.

### DESCRIPTION OF THE RELATED ARTS

Science and technology change with each passing day, the change of product design is inconceivable more and more, but the change still has a tendency, and the key tendency in size is that the weight must be more light, the thickness must be more thin, the length must be more short, the size must be more small, but along with the function is diversified and the structure is complicated the four key points are hard to achieve more and more. In the communication industry, the coaxial connector is used commonly in mobile phones, but the new generation mobile phone is not thicker than multi-centimeter, therefore various connectors used therein are forced to miniaturize, consequently the design structures of which have great varieties.

A disclosed coaxial connector, such as a Chinese patent number 01,125,198.0, includes a first resin member, a second resin member, a fixed terminal, a moveable terminal and an external terminal, the first resin member has a concave portion into which the center contact of a mating coaxial connector is inserted, the second resin member together with the first resin member form into an insulating case, the fixed terminal and the moveable terminal are sandwiched between the first and the second resin members. In order for the fixed terminal and the moveable terminal achieve a perfect location effect between the first and the second resin members, the fixed terminal the moveable terminal have half-circular concavities for holding the ribs on one of the resin member, then each rib is welding-fixed by the head chip of a welding device into a dome shape so as to hold the fixed terminal and moveable terminal, the other resin member has invert dome-shaped recess corresponding to the dome shape so as for the first and the second resin members inter-engaged correspondingly, although this kind of structure and assembly mode increase fixing precision when the fixed terminal and the moveable terminal are placed between the first and the second resin members, but also increase the process and time for manufacture and assembly, in fact, the rib of the resin member is welding-fixed by the head chip, if the terminals shift, even though the slightest shift, after soldering-fixed, the melted material deformed thermally by the had chip has fixed the terminal obliquely, this also results in the not-good-rate increasing.

Because the coaxial connector is very small in size, the flux contained in the soldering paste would be sucked into the first and the second resin members because of siphon phenomenon when soldering, although the coaxial connector has a groove having a V-shaped cross section on the resin member to prevent the flux contained in the soldering paste from permeating into the insulating case, but this kind of connector is very small in size, therefore the flux contained in the soldering paste is hard to be prevented from permeating into the insulating case completely.

Furthermore, the external terminal fastens the insulating case by the legs on the four corners thereof, i.e. the connector must control the precision of bending the four corners, and the connector is connected to the PCB with four corners, which is easy to result in ill efficiency in plane degree.

### SUMMARY OF THE INVENTION

The main object of the present invention is to provide a coaxial cable connector including a terminal seat formed by insert molding, so as to avoid resulting in terminal poor connection due to siphon phenomenon of the soldering paste during soldering.

Another object of the present invention is to provide a coaxial cable connector including a terminal seat formed by insert molding, which could control the position of each terminal precisely.

A further object of the present invention is to provide a coaxial cable connector including a terminal seat formed by insert molding, which could achieve a perfect plane degree through the holding portions on the two sides of the metal shell.

Hence, a coaxial cable connector in the present invention includes a metal shell, an insulating member, a terminal seat and an under cover. The upper side of the insulating member has a cylinder, the center of the cylinder has an insertion hole passing through the insulating member up and down; the base plate of the metal shell has a circular through hole extending upward a connecting portion for containing the insulating member; the terminal seat consists of a housing, a moveable terminal and a fixed terminal, the moveable terminal and the fixed terminal are positioned in the housing by insert molding, the center of the housing has a retaining chamber passing through up and down, the moveable terminal and the fixed terminal each has an extending portion projecting from the lateral sides of the housing respectively, the extending portion is bent into a soldering portion for soldered with the PCB, the moveable terminal and the fixed terminal stretch into the retaining chamber on the other end of the extending portion thereof respectively, the under cover is sheltered on the opening the containing chamber formed on the bottom of the housing.

Therein, the insulating member has a chassis on the lower side of the cylinder, the upper side of the retaining chamber on the terminal seat has a retaining room corresponding to the chassis above mentioned, the base plate of the metal shell is bent downward into a holding portions at appropriate positions on the two sides of the terminal seat, the holding portions are bent inward into abutting portions, the insulating member is placed on the upper side of the terminal seat, the holding portions of the metal shell are covered around the terminal seat and the under cover.

In assembly of the present invention, the under cover and the terminal seat are combined with the insulating member, then the foregoing combined body is held by the metal shell only, and the under cover, the terminal seat, the insulating member and the metal shell could be manufactured in the form of carrier strips respectively, each carrier strip has a plurality of under covers or terminal seats or insulating members or metal shells and components so on respectively, then the assembly is carried out in the form of carrier strips, later the finished products are cut off the carrier strips, in this way a plurality of finished products are accomplished only at one time, to achieve the producing process in which multi-group of connectors are manufactured jointly.

In order for those skilled in the arts could be more apparent with the structure and technique characteristics of the present invention, a preferred embodiment is described in detail hereafter with drawings.

### DETAILED DESCRIPTION OF THE PREFERRED EMBODIMENT

Please refer to FIGS. 1, 2 and 3, which are assembled perspective views and an exposed perspective view of the preferred embodiment of the invention, the coaxial cable connector includes a metal shell 1, an insulating member 2, a terminal seat 3 and an under cover 4. The upside of the insulating member 2 has a cylinder 22, the center of the cylinder 22 has an insertion hole 23 passing through the insulating member 2 up and down; the base plate 11 of the metal shell 1 has a circular through hole 12 which has a connecting portion 13 extending upward for containing the insulating member 2, in the present invention, the exterior wall of the cylinder 22 of the insulating member 2 further has at least a clasping strip 221, and the interior wall of the connecting portion 13 on the metal shell 1 has at least a clasping groove (not shown) the number of which is identical with that of the foregoing clasping strip 221, the shape of the clasping groove is complementary to that of the clasping strips 221, the clasping strip 221 is adapted to be pushed into the clasping groove for clasping location; please refer to FIG. 4 at the same time, the terminal seat 3 consists of a housing 31, a moveable terminal 32 and a fixed terminal 33, the moveable terminal 32 and the fixed terminal 33 are positioned in the housing 31 by insert molding, the main bodies of the moveable terminal 32 and the fixed terminal 33 have a plurality of fixing holes 323, 333 which will be filled and the moveable terminal 32 and the fixed terminal 33 will be fixed after the housing is injection molded in the mold, the center of the housing 31 has a retaining chamber 311 passing through up and down, the moveable terminal 32 and the fixed terminal 33 each has an extending portion 321, 331 projected from the lateral side of the housing 31 respectively, the extending portion 321, 331 each is bent into a soldering portion 322, 332 respectively for soldered with the PCB, in the present invention, the soldering portion 322, 332 of the moveable terminal 32 and the fixed terminal 33 is bent inward from the bottom edges of the lateral sides 313 of the housing 31 respectively, the soldering portions 322, 332 along with the main bodies of the moveable terminal 32 and the fixed terminal 33 each forms a pliers structure for clasping the lateral sides 313 of the housing 31, the moveable terminal 32 and the fixed terminal 31 stretch into the retaining chamber 311 on the opposite ends of the extending portions 321, 331 thereof respectively, the under cover 4 is sheltered on the opening the containing chamber 311 formed on the bottom side of the housing 31.

Therein, the insulating member 2 has a chassis 21 on the lower side of the cylinder 22, the upper side of the retaining chamber 311 on the terminal seat 31 has a first retaining room 314 corresponding to the chassis 21 above mentioned, so as the chassis 21 of the insulating member 2 could be placed onto the first retaining room 314 of the terminal seat 2, the base plate 11 of the metal shell 1 is bent downward into a holding portions 111 at appropriate positions of the two lateral sides of the terminal seat 3, the holding portion 111 is bent inward into an abutting portion 112, just like this, the insulating member 2 is placed on the upper side of the terminal seat 3, the holding portion 111 of the metal shell 1 is covered around the terminal seat 3 and the under cover 4, in the present invention, the chassis 21 of the insulating member 2 is circular, the chassis 21 is further cut out vertical sections 211 adjacent to the lateral sides of the terminal seat 3, the vertical sections 211 are used for discriminating direction in assembly and to avoid the metal shell 1 from clasping the chassis 21 of the insulating housing 2 when the holding portions 111 are bent.

The terminal seat 3 further has at least a locating protrusion 312 on an appropriate position of the top side of the housing 31, and the metal shell 1 has at least a locating recess 113 the number of which is identical to that of the locating protrusion 312 above mentioned on an appropriate position of the base plate 11 thereof, the shape of the recess 113 is complementary to that of the locating protrusion 312, so cause the locating recess 113 is adapted to accommodating the locating protrusion 312.

Please refer to FIG. 5, the lateral side of the under cover 4 has at least a clasping tab 41, the bottom side of the housing 31 on the terminal seat 3 has a second retaining room 315, the shape of the second retaining room 315 is complementary to the under cover 4, so as the under cover 4 could be engaged with the second retaining room 315.

The moveable terminal 32 and the fixed terminal 33 are placed inside the housing 31 by insert molding beforehand, therefore in assembly of the present invention, the under cover 4 and the terminal seat 3 could be combined with the insulating member 2 directly, then the foregoing combined body is held within the metal shell 1 only, please refer to FIG. 6, which is an assembled perspective view of a preferred embodiment of the present invention, and the under cover 4, the terminal seat 3, the insulating member 2 and the metal shell 1 are manufactured respectively in the form of carrier strips, each carrier strip has a plurality of under covers 4 or terminal seats 3 or insulating members 2 or metal shells 1 and components so on, the assembly process is carried out in the form of carrier strips in upside down position, the carrier strip of the under cover 4 is placed on the upside of the carrier strip of the terminal seat 3, then the carrier strip of the terminal seat 3 is placed on the upside of the carrier strip of the insulating member 2, since the under cover 4 could be fix-placed on the second retaining room 315 of the terminal seat 3 and the terminal seat 3 could be fix-placed on the chassis 21 of the insulating member 2, just like so, a combined body could be achieved which consists of an insulating member 2, a terminal seat 3 and an under cover 2, then the cylinder 22 of the insulating member 2 is placed into the through hole 12 of the metal shell 1, later the holding portions 111 of the metal shell 1 are bent inward so as for the holding portions 111 holding the combined body into a finished product, finally the finished product is cut off the carrier strips, thereby a plurality of finished products are accomplished only at one time.

The structures and embodiment mode disclosed in the present invention are illustrative but not restrictive to the present invention, any modifications made by those known the arts through the description of the invention without departing from the spirit of the present invention are considered as like structures and covered in the claims of the present invention.

### BRIEF DESCRIPTION OF THE DRAWINGS

FIG. 1 is an assembled perspective view of the coaxial cable connector of the present invention.

FIG. 2 is an assembled perspective view of the coaxial cable connector of the present invention from another angle.

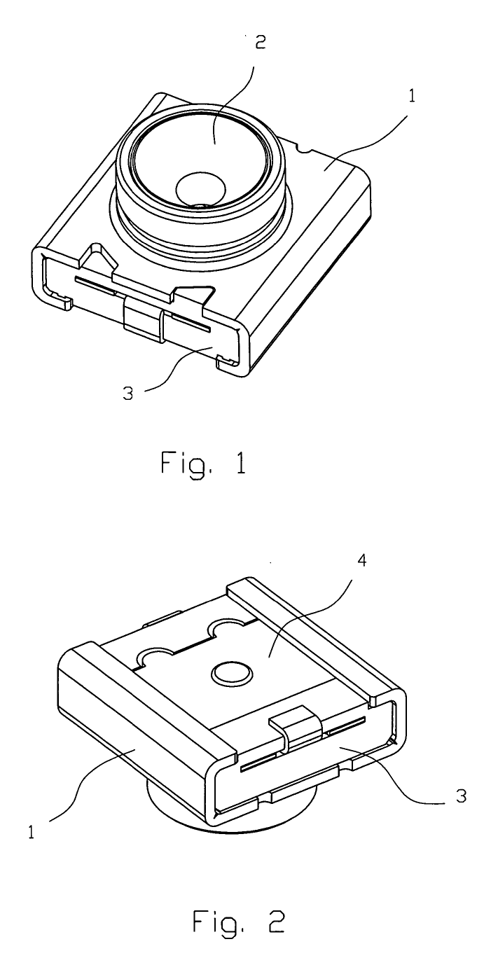

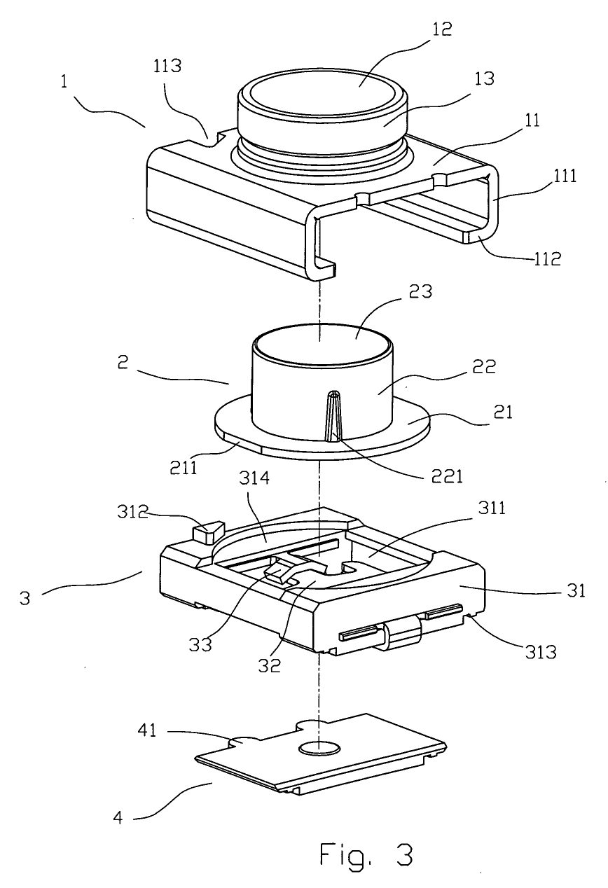

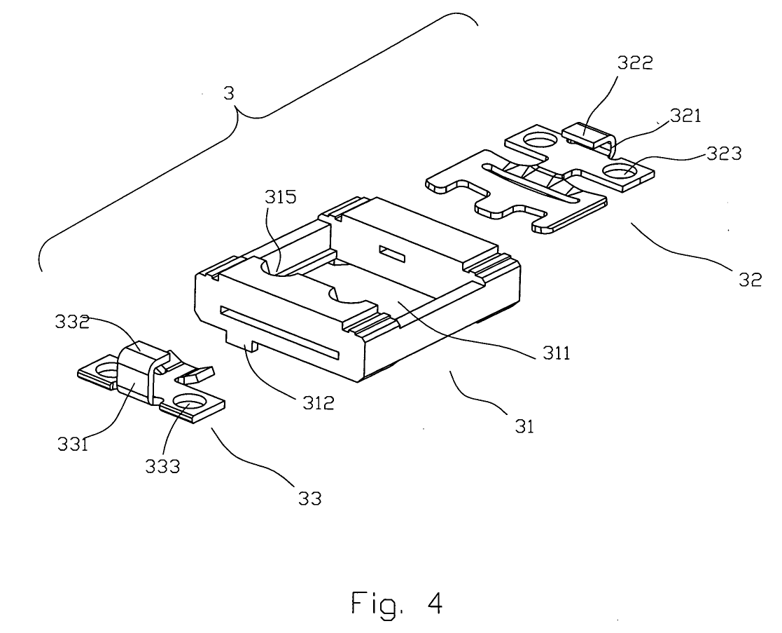

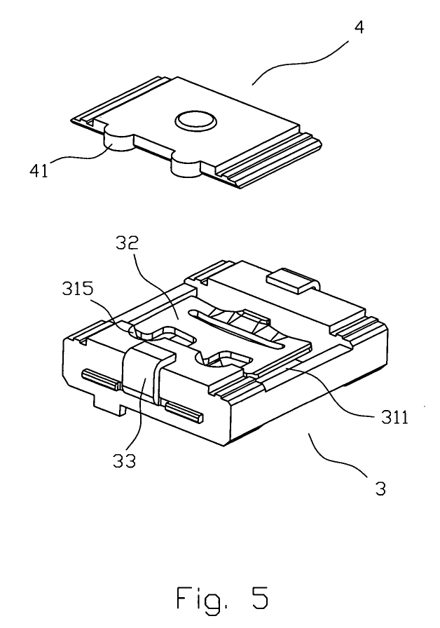

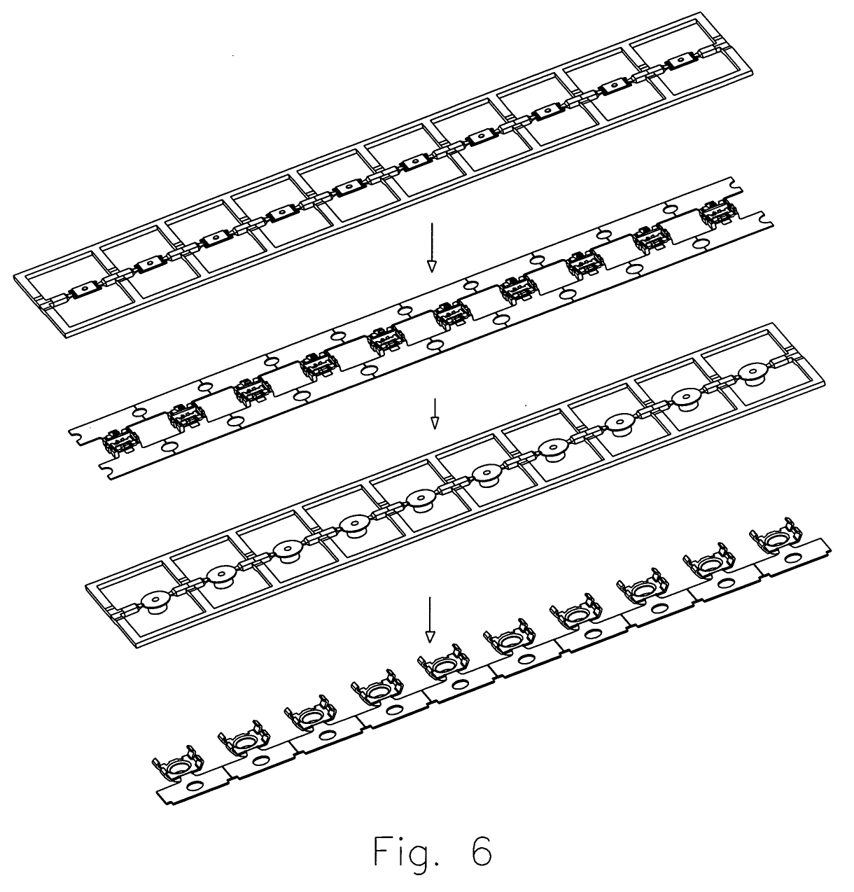

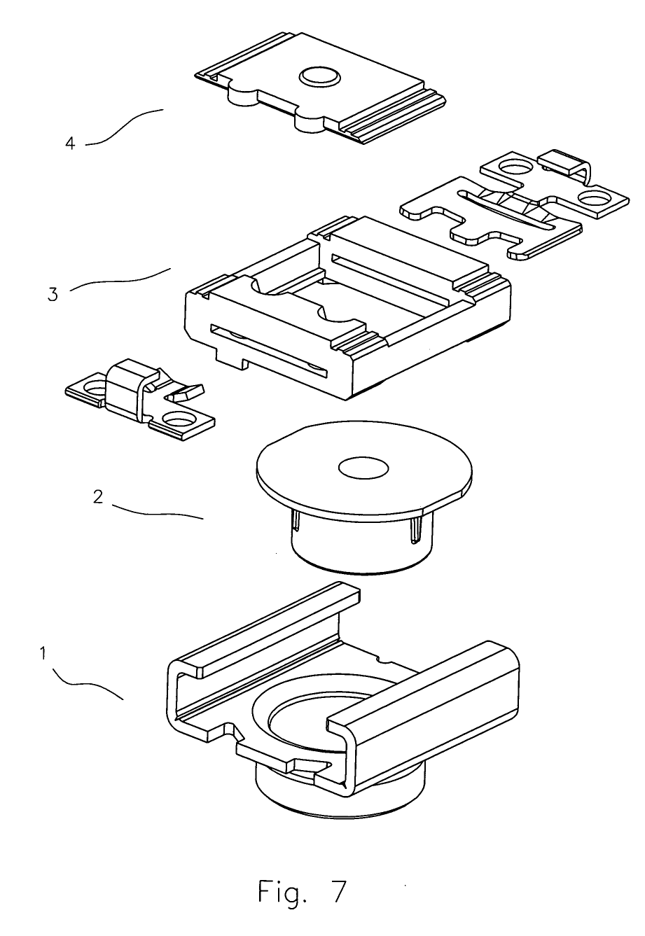

What is claimed is:

1-6. (canceled)

7. An assembly method of the coaxial cable connector, which comprises a metal shell, an insulating member, a terminal seat and an under cover, wherein said terminal seat is formed with a moveable terminal, a fixed terminal and a housing by insert molding, comprising:
producing the metal shell, the insulating member, the terminal seat and the under cover in the form of carrier strips, each component carrier strip having a plurality of metal shells or insulating members or terminal seats or under covers;
carrying out the assembly process in the form of carrier strips in upside down position;
assembling the carrier strips of the under cover, the terminal seat and the insulating member into a plurality of combined bodies;
placing the combined bodies onto the carrier strip of the metal shell;
making the metal shells holding the combined bodies into finished products respectively;
cutting finished products off the carrier strips.
